(19) United States
(12) Patent Application Publication
(10) Pub. No.: US 2013/0248731 A1
(43) Pub. Date: Sep. 26, 2013

(54) ELECTRON BEAM APPARATUS AND LENS ARRAY

(71) Applicant: HITACHI HIGH-TECHNOLOGIES CORPORATION, Tokyo (JP)

(72) Inventors: Sayaka TANIMOTO, Kokubunji (JP); Hiroya OHTA, Kokubunji (JP); Makoto SAKAKIBARA, Fuchu (JP); Momoyo ENYAMA, Kunitachi (JP); Kenji TANIMOTO, Hitachinaka (JP)

(73) Assignee: HITACHI HIGH-TECHNOLOGIES CORPORATION, Tokyo (JP)

(21) Appl. No.: 13/733,955

(22) Filed: Jan. 4, 2013

(30) Foreign Application Priority Data
Mar. 21, 2012 (JP) 2012-063816

(51) Int. Cl. H01J 37/10

(52) U.S. Cl. CPC H01J 37/10
USPC 250/396 R

(57) ABSTRACT

There is provided both an electron beam apparatus and a lens array, capable of correcting a curvature of field aberration under various optical conditions. The electron beam apparatus comprises the lens array having a plurality of electrodes, and multiple openings are formed in the respective electrodes. An opening diameter distribution with respect to the respective opening diameters of the plural openings formed in the respective electrodes are individually set, and voltages applied to the respective electrodes are independently controlled to thereby independently adjust an image forming position of a reference beam, and a curvature of the lens array image surface.

### CLAIM OF PRIORITY

The present application claims priority from Japanese patent application JP 2012-063816 filed on Mar. 21, 2012, the content of which is hereby incorporated by reference into this application.

### FIELD OF THE INVENTION

The present invention relates to an electron beam application technology, and in particular, to an electron beam apparatus such as an inspection apparatus, a microscope, and so forth, used in a semiconductor process, and a lens array incorporated therein.

### BACKGROUND OF THE INVENTION

In a semiconductor process, use is made of an electron microscope for irradiating an electron beam called a primary beam onto a specimen to thereby make an observation of a pattern, and a structure, formed on the specimen such as a wafer, and so forth from a signal of a secondary electron, a reflection electron, and so forth (hereinafter called a secondary beam), that is, to carry out observation, measurement, inspection, and suchlike. The electron beam apparatus includes, for example, an electron beam measuring apparatus for measuring a shape and a size, an electron beam inspection apparatus for use in the inspection of a pattern formed on a wafer, and so forth.

In these electron microscopes, enhancement in an inspection speed and a measurement speed is an important problem, and various schemes have been proposed in order to solve the problem. For example, in a multi-beam electron inspection apparatus proposed in Japanese Unexamined Patent Application Publication No. 2001-267221, a scheme has been proposed whereby multiple beams formed by splitting a beam with the use of a plate having plural openings are caused to individually focus using lenses arranged in array to thereby form multiple intermediate images, whereupon the plural intermediate images are projected on a specimen using an objective lens, and a deflector, provided in the downstream, to be then scanned.

With the multi-beam electron inspection apparatus described as above, uniformity in beam diameter is one of factors deciding a measurement precision, and an inspection precision. For this reason, there is the need for correcting a curvature of field aberration of an objective lens for use in projecting the plural intermediate images on the specimen. The curvature of field represents a phenomenon in which an image surface projected by a lens is not flat, meaning that if a beam passing through a track close to the center axis is brought to a focus, a beam passing through a track away from the center axis will be out of focus in the optical system of the multi-beam electron inspection apparatus.

In contrast, for example, with an electron beam exposure apparatus disclosed in Japanese Unexamined Patent Application Publication No. 2007-123599, there has been shown another scheme for correcting the curvature of field aberration. More specifically, the curvature of field of a lens provided in the downstream is found beforehand, and openings provided in at least one plate of electrode among three plates of electrodes composing a lens array is set to have diameters not less than two types so as to correct the curvature of field. By so doing, the image surface of the lens array has a preset curvature, thereby offsetting the curvature of field of the objective lens.

### SUMMARY OF THE INVENTION

In the case of correcting the curvature of field aberration of an objective lens using, for example, the scheme disclosed in Japanese Unexamined Patent Application Publication No. 2007-123599, a likely problem will be that the diameter of the opening of the lens array cannot be easily changed, and therefore, an optical condition under which the curvature of field can be corrected will be restricted. More specifically, if a magnification of the objective lens is changed after once the lens array is installed in the apparatus, it will be difficult to control the curvature of field of the objective lens so as to match a change in the curvature of field aberration of the objective lens, accompanying a change in the magnification.

As a method for avoiding this problem, it is conceivable to use a lens array where individual voltages can be set to respective electron beams, such as a lens array shown in, for example, Japanese Unexamined Patent Application Publication No. 2001-267221. More specifically, the curvature of a lens array image surface can theoretically be controlled by, for example, individually controlling a voltage for every electron beam in such a way as to match a change in the curvature of field aberration although this is not described in the relevant literature. However, in reality, many technical problems are involved in preparing the lens array described in Japanese Unexamined Patent Application Publication No. 2001-267221. Further, in consideration of many power supplies, and circuits, necessary in order to control voltages applied to the respective electron beams, it can be said that this method has a problem from a cost point of view, as well.

Meanwhile, as a method for avoiding this problem without setting individual voltages to the respective electron beams, adjustment of a voltage applied to the lens array can be cited. This is because an applied voltage can be controlled from outside even after the lens array is installed in the apparatus. However, even if the voltage applied to the lens array disclosed in Japanese Unexamined Patent Application Publication No. 2007-123599 is adjusted, an image forming position of the beam passing through the track close to the center axis, intrinsically posing no problem with the curvature of field, undergoes a change concurrently with a change in the curvature of the lens array image surface. As a result, not only an optical condition on the downstream side of the lens array should be changed again, but also the magnification of an image projected on the specimen, as well, is changed.

The invention has been developed under circumstances described as above, and it is one of objects of the invention to provide both an electron beam apparatus and a lens array, capable of correcting a curvature of field aberration under various optical conditions. The above and other objects, novel features of the present invention will be apparent from the following description and the accompanying drawings.

The gist of a representative means for solving the problem disclosed under the present application is described as follows.

The lens array according to one aspect of the invention is capable of causing multiple electron beams to be individually converged on individual axes, respectively, thereby forming an image-forming surface of the plural electron beams, having a unit for adjusting a shape of the image-forming surface in response to a change in various parameters for setting an optical condition. The relevant unit independently controls an image forming position of one length of electron beam among the plural electron beams, serving as a reference, and a curvature of the image-forming surface.

According to the one aspect of the invention, a curvature of field aberration can be corrected under a variety of optical conditions.

### BRIEF DESCRIPTION OF THE DRAWINGS

FIG. 1 is a view showing an example of the schematic configuration of an electron beam apparatus according to a first embodiment of the invention;

FIG. 2A is a view showing one example of a curvature of field aberration in the case of using a lens array as a comparative example;

FIG. 2B is a view showing one example of a curvature of field aberration in the case of using a lens array as a comparative example;

FIG. 2C is a view showing one example of a curvature of field aberration in the case of using a lens array as a comparative example;

FIG. 2D is a view showing one example of a curvature of field aberration in the case of using a lens array as a comparative example;

FIG. 2E is a view showing one example of a curvature of field aberration in the case of using a lens array according to a first embodiment of the invention;

FIG. 3A is a schematic representation showing an example of the configuration of the lens array according to the first embodiment;

FIG. 3B is a schematic representation showing another example of the configuration of the lens array according to the first embodiment;

FIG. 3C is a schematic representation showing still another example of the configuration of the lens array according to the first embodiment;

FIG. 4A is a schematic illustration for describing the principle underlying a scheme for controlling the curvature of a lens array image surface using the lens array according to the first embodiment;

FIG. 4B is another schematic illustration for describing the principle underlying the scheme for controlling the curvature of a lens array image surface using the lens array according to the first embodiment;

FIG. 4C is still another schematic illustration for describing the principle underlying the scheme for controlling the curvature of a lens array image surface using the lens array according to the first embodiment;

FIG. 4D is a further schematic illustration for describing the principle underlying the scheme for controlling the curvature of a lens array image surface using the lens array according to the first embodiment;

FIG. 5A is a schematic illustration for describing a scheme for correcting a spherical aberration using the lens array according to the first embodiment;

FIG. 5B is another schematic illustration for describing a scheme for correcting a spherical aberration using the lens array according to the first embodiment;

FIG. 6 is a flow chart showing an example of a procedure for setting an optical condition of the electron beam apparatus according to the first embodiment;

FIG. 7A is a schematic illustration showing an example of a method for deciding voltages to be applied in the lens array according to the first embodiment;

FIG. 7B is another schematic illustration showing an example of a method for deciding voltages to be applied in the lens array according to the first embodiment;

FIG. 8A is a schematic representation showing an example of the configuration of a lens array in an electron beam apparatus according to a second embodiment of the invention;

FIG. 8B is a schematic representation showing another example of the configuration of a lens array in an electron beam apparatus according to a second embodiment of the invention;

FIG. 8C is a schematic representation showing still another example of the configuration of a lens array in an electron beam apparatus according to a second embodiment of the invention;

FIG. 9A is a schematic representation showing an example of the configuration of a lens array in an electron beam apparatus according to a third embodiment of the invention;

FIG. 9B is a schematic representation showing another example of the configuration of a lens array in an electron beam apparatus according to a third embodiment of the invention;

FIG. 9C is a schematic illustration for showing the principle behind a scheme for controlling the curvature of the lens array image surface using the lens array according to the third embodiment of the invention;

FIG. 9D is a schematic illustration for showing the principle behind the scheme for controlling the curvature of the lens array image surface using the lens array according to the third embodiment of the invention;

FIG. 10A is a schematic illustration for showing the principle behind a scheme for controlling the curvature of the lens array image surface using the lens array according to a fourth embodiment of the invention;

FIG. 10B is a schematic illustration for showing the principle behind a scheme for controlling the curvature of the lens array image surface using the lens array according to the fourth embodiment of the invention;

FIG. 11A is a schematic representation showing an example of the configuration of the lens array according to the fourth embodiment of the invention;

FIG. 11B is a schematic representation showing another example of the configuration of the lens array according to the fourth embodiment of the invention;

FIG. 11C is a schematic representation showing still another example of the configuration of the lens array according to the fourth embodiment of the is invention; and

FIG. 12 is a schematic diagram showing an example of the construction of a reflecting mirror included in an electron beam apparatus according to the fifth embodiment of the invention.

### DETAILED DESCRIPTION OF THE PREFERRED EMBODIMENTS

In any of embodiments described hereinafter, the embodiment is divided into plural sections or plural embodiments as necessary for convenience's sake, however, it is to be understood that these sections or these embodiments are not unrelated to each other unless otherwise specified, and one part represents a variation, detail, and supplementary remarks of a part or the whole of the other. Further, with the embodiments described hereinafter, it is to be understood that if the number of elements, and so forth (including the number of pieces, a numerical value, a quantity, a scope, and so forth) are referred to, the number, and so forth be not limited to a specific number, and may be not less than the specific number, or less than the specific number unless otherwise specified, and obviously theoretically limited to the specific number.

Still further, in the embodiments described hereinafter, it is needless to say that constituent elements thereof (including an element step, and so forth) are not necessarily essential unless otherwise specified, and obviously theoretically considered as essential. Similarly, with the embodiments described hereinafter, it is to be understood that if a shape of the constituent element, and so forth, and a positional relationship are referred to, a constituent element that is effectively approximated thereto, or is analogues thereto is included unless otherwise specified, and obviously theoretically considered otherwise. The same can be said of the value and the scope.

Embodiments of the invention are described in detail hereinafter with reference to the drawings. Further, in all the figures for describing the embodiments of the invention, members identical to each other are denoted by like reference numerals, omitting repeated description thereof.

### First Embodiment

In a microscope for application to a semiconductor process, such as, for example, an electron beam inspection apparatus, an electron beam measuring apparatus, and so forth, the variety of controls as to an optical condition, according to a specimen, are required. Under such circumstances, a lens array according to the related art is unable to independently control an image forming position using a lens close to a center axis, and a curvature of a lens array image surface (a lens array image-forming surface or a crossover image surface), so that it has become difficult to have a desirable optical condition compatible with the correction of the curvature of field aberration. In the first embodiment of the invention, with an eye on this point, it is intended to implement an electron beam apparatus capable of independently controlling the image forming position by the lens close to the center axis, and the curvature of the lens array image surface. As one of specific unit (will be described in detail later on) for implementing the above, there is adopted a configuration where at least four plates of electrodes for forming a lens array are prepared, and an individual voltage can be applied to at least the two plates of the electrodes, respectively. Openings provided in the two plates of the electrodes to which the individual voltage can be applied, respectively, differ in size from each other. The diameter of the opening in at least one plate of the electrode of the two plates of the electrodes is set so as to vary according to a distance from the center axis.

### <Overall Configuration of an Electron Beam Apparatus, and an Operation Thereof>

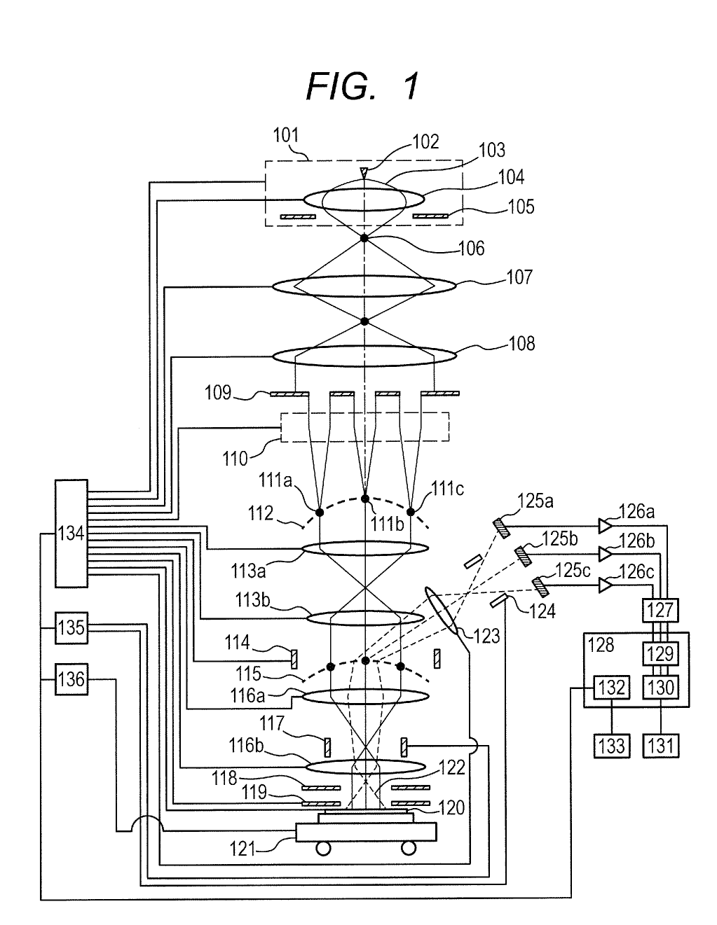

FIG. 1 is a view showing an example of the schematic configuration of an electron beam apparatus according to a first embodiment of the invention. In FIG. 1, a dash and dotted line is an axis where the respective axes of symmetry of optical systems formed so as to be substantially of rotational symmetry are to coincide with each other, the axis serving as a reference for a primary beam optical path. The axis is hereinafter referred to as a center axis. An electron gun 101 is comprised of a cathode 102 made of material low in work function, an anode 105 having a high voltage against the cathode 102, and a magnetic field superimposing lens 104 for superimposing a magnetic field on an accelerating electric field formed between the cathode and the anode. With the present embodiment, use is made of a Schottky type cathode where a large current is easily obtainable, and electron emission is stable. A primary beam 103 emitted from the cathode 102 is accelerated toward the anode 105 while being subjected to a convergence action by the magnetic field superimposing lens 104 (an electromagnetic lens). Reference numeral 106 denotes a crossover. A condenser lens 107 forms an image of the crossover 106 at a desired magnification, thereby forming a first crossover image. A collimator lens 108 shapes up primary beams spread out from the first crossover image so as to be substantially in parallel with each other. With the present embodiment, the condenser lens 107, and the collimator lens 108 are each an electromagnetic lens. Reference numeral 109 denotes an aperture array where openings are two-dimensionally lined up on one substrate to thereby split the primary beam into multiple beams. With the present embodiment, the aperture array has 25 openings, and the primary beam is split into 25 lengths of the beams. FIG. 1 shows only 3 lengths of the beams among those beams.

The split primary beams are individually converged by a lens array 110, and 25 pieces of crossover images are formed on a lens array image surface (a lens array image-forming surface, or a crossover image surface) 112. The lens array image surface 112 is a curved surface symmetrical around the center axis as described later on. Reference numerals 111a, 111b, 111c each are the crossover image with respect to each of the 3 lengths of the beams shown in the figure. The 25 lengths of the beams are subjected to a convergence action of the lens array, subsequently forming images on a transfer lens image-forming surface 115 by the respective convergence actions of transfer lenses 113a and 113b.

A Wien filter 114 is provided in the vicinity of the transfer lens image-forming surface 115. The Wien filter 114 causes a magnetic field and an electric field orthogonal to each other to be generated in a plane substantially perpendicular to the center axis to thereby impart a deflection angle corresponding to the energy of a passing electron to the passing electron. With the present embodiment, the intensity of the magnetic field, and the intensity of the electric field are set such that the primary beams travel in a straight line.

Reference numerals 116a, 116b each are an objective lens, being two electromagnetic lenses in pairs. A negative voltage is applied to a specimen 120, and an electric field for causing the primary beams to decelerate is formed between the specimen 120 and a ground electrode 118 connected to a ground voltage. Meanwhile, a surface electric field control electrode 119 is an electrode for adjustment of the intensity of an electric field in the vicinity of the surface of the specimen 120. An electric field generated by the ground electrode 118, the surface electric field control electrode 119, and the specimen 120 acts as an electrostatic lens against the primary beams.

The 25 lengths of the primary beams are subjected to a convergence action of the electrostatic lens, and the respective convergence actions of the objective lenses 116, 116b, whereupon the 25 pieces of the crossover images are finally formed on the specimen 120.

A deflector 117 of an electrostatic octupole type is installed inside the objective lenses. Upon a scan-signal generated from a scan-signal generation circuit 135 being inputted to the deflector 117, substantially uniform deflecting electric fields are formed in the deflector, and the 25 lengths of the primary beams passing through the deflector are subjected to deflection actions in directions substantially identical to each other, and at angles substantially identical to each other, respectively, to scan over the specimen 120. Because the specimen 120 is mounted on a stage 121 movable by a control of a control device 136, desired locations on the specimen are scanned by the 25 lengths of the primary beams, respectively.

The primary beams having reached the surface of the specimen 120 come into mutual actions with a constituent substance of the surface of the specimen. Respective flows of secondary electrons, such as a reflection electron, a secondary electron, an Auger electron, and so forth, generated from the specimen 120, as a result of the mutual actions, are referred to as a secondary beam hereinafter. With the present embodiment, since the 25 lengths of the primary beams reach the surface of the specimen, 25 lengths of the secondary beams are generated, however, FIG. 1 shows the 3 lengths of the primary beams, and therefore, 3 lengths of the secondary beams are indicated by reference numeral 122, and a dotted line, respectively, to be shown in the figure.

Because the negative voltage has been applied to the specimen, the secondary beams generated from the specimen 120 are accelerated toward the objective lenses 116a, 116b. Thereafter, the secondary beams are subjected to the respective convergence actions of the objective lenses 116, 116b, and are further subjected to a reflection action of the Wien filter 114. By so doing, the tracks of the secondary beams are separated from the tracks of the primary beams, respectively. The secondary beams in the respective tracks separated from the respective tracks of the primary beams are subjected to a convergence action of an electromagnetic lens 123 acting only on the secondary beams. A swing-over deflector 124 is a deflector for causing the secondary beams to always fall on respective detectors corresponding thereto, and a scan-signal in sync with the scan-signal inputted to the deflector 117 is inputted to the swing-over deflector 124 by the scan-signal generation circuit 135. More specifically, the secondary beams (the 3 lengths of the secondary beams shown in FIG. 1) are individually detected by the detectors 125a, 125b, 125c, respectively, by the agency of convergence•deflection by the electromagnetic lens 123, and the swing-over deflector 124.

Signals detected by the detectors 125a, 125b, 125c, respectively, are amplified by amplifiers 126a, 126b, and 126c, respectively, to be digitized by an A/D converter 127.

Digitized signals in the form of image data are once stored in a storage 129 inside a system control unit 128. Thereafter, an operation part 130 executes computation of various statistics of an image. Computed statistics are displayed on an image display unit 131. Processes from the detection of the secondary beams up to the computation of the statistics are executed in parallel with each other on a detector-by-detector basis. Further, reference numeral 133 denotes an input unit including a keyboard, and a mouse, serving as the user-interface of the system control unit 128. Further, the condenser lens 107, and the collimator lens 108 are primarily responsible for shaping up an electron beam from the electron gun 101, therefore being called an irradiation optical system, while the transfer lenses 113a, 113b, and the objective lenses 116a, 116b are primarily responsible for projecting the electron beam obtained via the irradiation optical system on the specimen 120, therefore being called a projection optical system.

Next, controls of respective optical elements are described. An optical system control circuit 134 controls the respective optical elements in a unified manner according to a measuring-condition setting program 132 installed in the system control unit 128. More specifically, the optical system control circuit 134 controls a voltage applied to an extraction electrode (not shown) mounted in the electron gun 101, an acceleration voltage of the electron gun (a voltage applied between the cathode 102 and the anode 105), and a current to be applied to the electromagnetic lens 104 for superimposing the magnetic field inside the electron gun. Further, the optical system control circuit 134 controls respective currents applied to the condenser lens 107, and the collimator lens 108, and a voltage applied to the lens array 110. Still further, the optical system control circuit 134 controls respective currents applied to the transfer lenses 113a, 113b, and the objective lenses 116a, 116b. Yet further, the optical system control circuit 134 controls respective voltages applied to the ground electrode 118, and the surface electric field control electrode 119. Further, the optical system control circuit 134 controls a voltage as well as a current applied to the Wien filter 114. Furthermore, the optical system control circuit 134 controls a current applied to the electromagnetic lens 123.

### <Gist of a Scheme for Correcting a Curvature of Field Aberration>

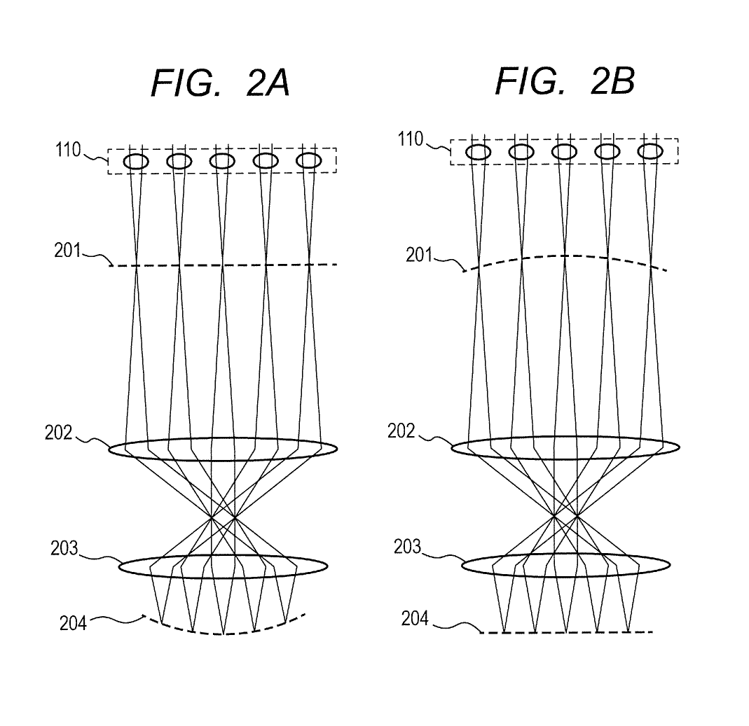

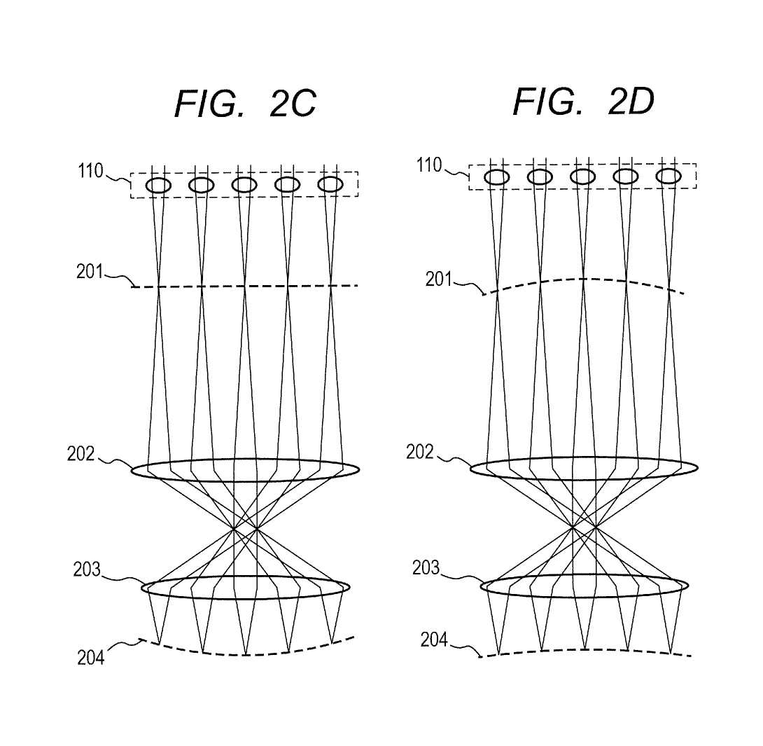

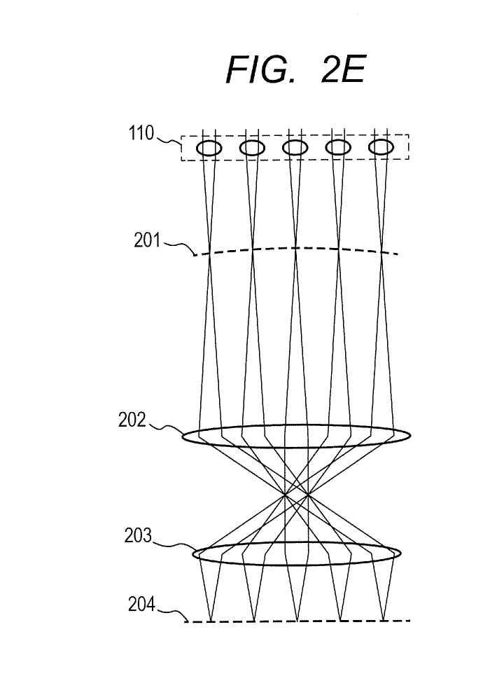

Now, the gist of the correction of a curvature of field aberration is described with reference to FIGS. 2A to 2E. FIGS. 2A to 2D each are a view showing one example of a curvature of field aberration in the case of using a lens array as a comparative example, while FIG. 2E is a view showing one example of a curvature of field aberration in the case of using a lens array according to the first embodiment of the invention. In these figures, two lenses are shown between the lens array image surface (the lens array image-forming surface or the crossover image surface) and a specimen, for the sake of brevity, showing the minimum requirements, and even if three or more lenses are provided between the lens array image surface and the specimen, as shown in FIG. 1, and so forth, the same effect can be obtained.

FIG. 2A shows the respective tracks of beams (5 lengths of beams in this case) in the case where the correction of the curvature of field aberration is not executed using the lens array 110. In this case, the lens array 110 imparts an equal convergence action to alt the 5 lengths of the beams, so that the lens array image surface (the lens array image-forming surface or the crossover image surface) 201 is seen as a flat surface. On the other hand, respective image forming positions of the beams are dependent on respective distances from the center axis owing to the respective curvature of field aberration of lenses 202, 203, so that the image forming positions differ in the vertical direction from each is other. Accordingly, even if the focus of the beam at the center is aligned with a specimen surface, the respective focuses of the beams away from the center axis will be off the specimen surface on an image-forming surface 204 on the specimen.

In contrast, FIG. 2B is a view for describing the scheme for correcting the curvature of field aberration in the case of the electron beam exposure apparatus disclosed in Japanese Unexamined Patent Application Publication No. 2007-123599. With this scheme, the respective curvature of field aberrations of the lenses 202, 203 are found beforehand, and subsequently, the respective diameters of openings in the lens array 110 are adjusted, thereby controlling the curvature of the lens array image surface (the lens array image-forming surface or the crossover image surface) 201. As a result, the respective focuses of all the beams can be aligned with the image surface on the image-forming surface 204 on the specimen.

Now, referring to FIGS. 2C, 2D, let us think about the case where the respective magnifications of the lenses 202, 203, in FIGS. 2A, 2B, respectively, are varied to thereby vary an interval between the respective beams, on the image surface 204 on the specimen. Thus, variation in magnification, caused by changing a balance in strength, between two or more lenses, without changing a focus position, is called a zoom. A new problem arising at this point in time is a change in the curvature of field aberration, accompanying a change in magnification. FIG. 2C is a view showing the respective tracks of the beams, on the image-forming surface 204, in the case where the correction of the curvature of field aberration is not executed by the lens array 110. In comparison with FIG. 2A showing a state prior to the change in magnification, it is found that a similar curvature of field aberration has occurred, and a curvature thereof has varied.

Further, even in the case of using the scheme for correcting the curvature of field aberration as shown in Japanese Unexamined Patent Application Publication No. 2007-123599, the curvature of field aberration is found by assuming a specific magnification, and on the basis of the curvature of field aberration, the respective diameters of openings in the lens array 110 are adjusted, so that if a magnification differs from the assumed magnification, it will be difficult to carry out an optimum correction. For example, an excessive correction occurs as shown in FIG. 2 D, and if the focus of the beam at the center is aligned with the specimen surface on the image-forming surface 204 on the specimen, the focuses of respective beams, dependent on a distance from the center axis, will be off the specimen surface. Conversely, in the case of an insufficient correction, the focuses of the respective beams, dependent on a distance from the center axis, will be off the specimen surface although not shown in the figure.

In contrast, with the lens array 110 according to the first embodiment, the curvature of the image surface of the lens array 110 is optimally controlled such that even if the magnification of a zoom lens is changed, the curvature of field on the specimen is minimized. More specifically, by installing the lens array 110 capable of adjusting as appropriate the curvature of the lens array image surface (the lens array image-forming surface, or the crossover image surface) so as to match a change in the curvature of field aberration, accompanying a change in strength, and so forth of the lenses 202, 203, respectively, as shown in FIG. 2E, it is possible to obtain the image surface 204 with which the focuses of all the beams can be aligned regardless of the distance from the center axis.

### <The Lens Array in Detail>

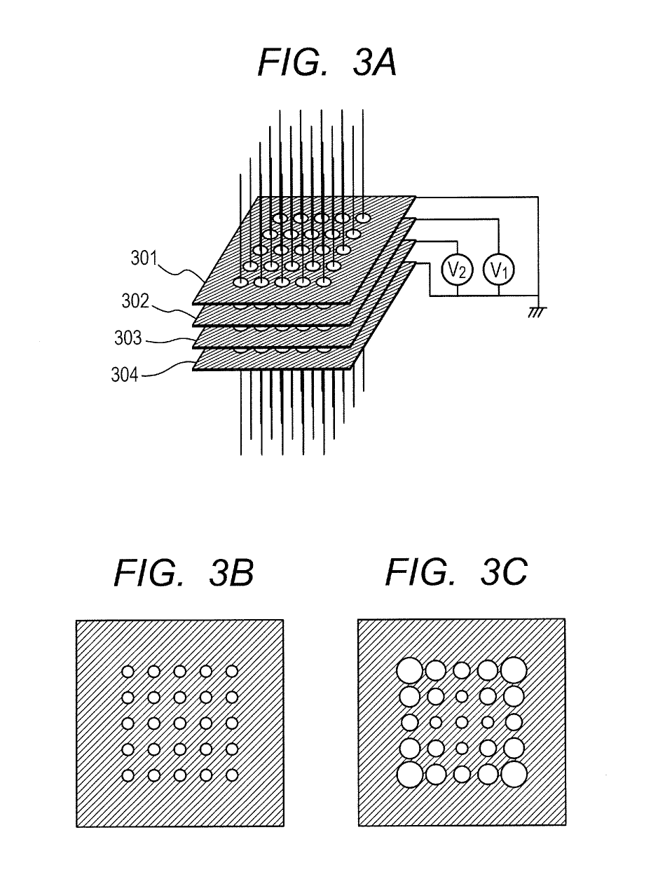

An example of the configuration of the lens array according to the first embodiment is described with reference to FIGS. 3A to 3C. The lens array shown in FIG. 3A is comprised of four plates of electrodes, including a first electrode 301, a second electrode 302, a third electrode 303, and a fourth electrode 304, provided in this order from the upstream side (a side of the lens array, adjacent to the electron gun). The respective electrodes have multiple openings. In FIG. 3A, there are formed 25 pieces of the openings so as to correspond to 25 lengths of beams. The openings each are circular in shape, and the openings in the respective electrodes are disposed such that the beam axis of each of the 25 lengths of the beams, indicated by a solid line in the figure, penetrates through the center of the opening. A common voltage {in this case, the ground voltage (a housing voltage of the electron beam apparatus of FIG. 1)} is applied to the first electrode 301, and the fourth electrode 304, respectively, while a power supply is independently connected to the second electrode 302, and the third electrode 303, respectively. The voltage of the second electrode 302 is V1, and the voltage of the third electrode 303 is V2. In this case, V1 is identical in polarity to V2.

FIG. 3B shows the diameter of each of the openings, and a layout of the openings with respect to the first, second, and fourth electrodes (301, 302, 304), respectively, by way of example. FIG. 3C shows the diameters of the respective openings, and a layout of the openings the with respect to the third electrode 303 by way of example. The respective diameters of 25 pieces of the openings are all equal with respect to the first, second, and fourth electrodes, respectively. In contrast, the openings in the third electrode 303 are formed such that the further the opening is away from the center of an array, the larger the diameter of the opening is.

The lens array shown in FIG. 3A can be said as one type of the einzel lens because the first electrode 301, serving as an inlet, and the fourth electrode 304, serving as an outlet, are each at the same voltage. The einzel lens makes use of the rotational symmetry of a leakage (the fringe) of an electric field, formed on the opening of the electrode, while causing a beam to accelerate or decelerate, to thereby impart the effect of a convex lens to the electron beam, the strength of the lens being decided by the diameter of the opening in the electrode to which a voltage is applied, and a voltage. In the case of FIG. 3A, the electrodes where respective voltages are applied are two electrodes including the second electrode 302, and the third electrode 303, and therefore, the lens array can be approximated by a 2-stage lens, that is, a lens whose strength is decided by the voltage V1 of the second electrode 302, and a lens whose strength is decided by the voltage V2 of the third electrode 303.

The respective diameters of the openings in the second electrode are all equal, as shown in FIG. 3B, so that the respective lenses whose strength are decided by the voltage V1 have an identical lens strength against all the 25 lengths of the beams. On the other hand, the openings of the third electrode 303 are formed such that the further the opening is away from the center of the array, the larger the diameter of the opening is, as shown in FIG. 3C, so that the respective lenses whose strength is decided by the voltage V2 have large lens strength against the beam on the center axis, while having the smaller lens strength against the respective beams other than the beam on the center axis, the further the respective beams are away from the center axis.

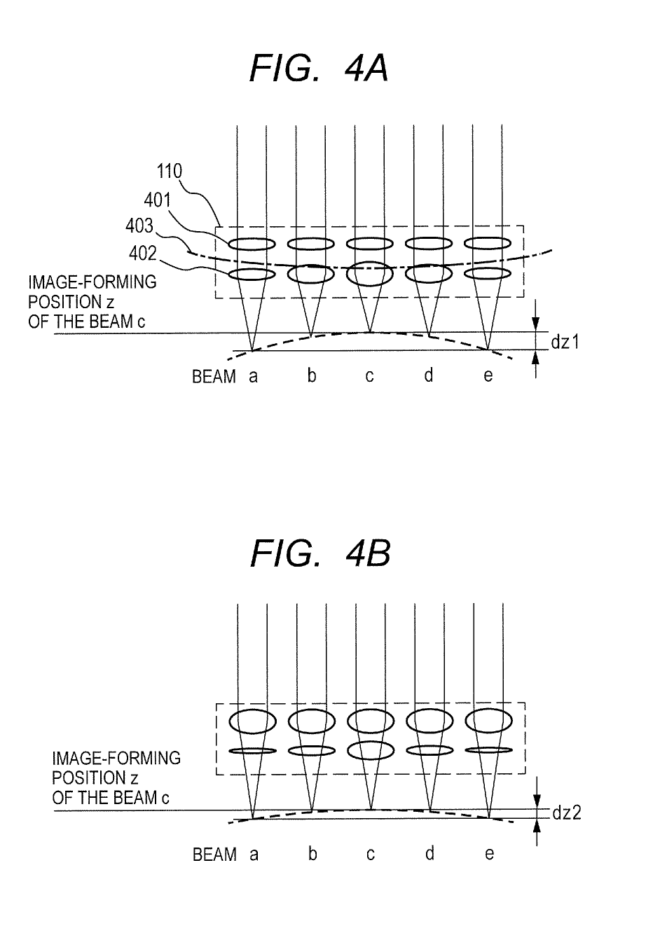

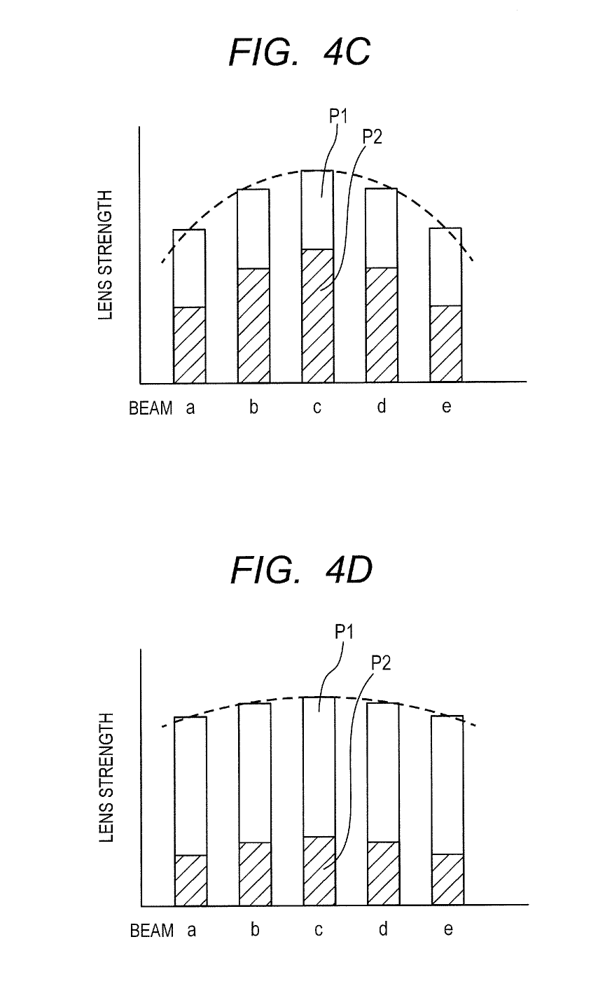

Next, referring to FIGS. 4A to 4D, there is described hereinafter the principle underlying the scheme for controlling the curvature of the lens array image surface (the lens array image-forming surface or the crossover image surface) using the lens array 110 according to the first embodiment. In the figure, a lens 401 is a lens whose strength is decided by the voltage V1 of the second electrode, and a lens 402 is a lens whose strength is decided by the voltage V2 of the third electrode.

FIG. 4A is a schematic diagram showing the respective tracks of the 5 length of the beams at various distances from the center axis in the case where the curvature of the lens array image surface (the lens array image-forming surface or the crossover image surface) is adjusted such that a difference in image forming position between the center beam (c) and the beam (a) away from the center axis will be dz1. FIG. 4B is a schematic diagram showing the respective tracks of the 5 length of the beams at various distances from the center axis in the case where the curvature of the lens array image surface is adjusted such that a difference in image forming position between the center beam (c) and the beam (a) away from the center axis will be dz2. Herein, dz1 is larger in value than dz2, and the curvature of the lens array image surface in FIG. 4A is greater than the same in FIG. 4B. Meanwhile, the image forming position of the center beam in FIG. 4A is identical to that in FIG. 4B.

In order to execute such a control as described, it need only be sufficient to control respective strengths of the lenses 401, 402, as follows. In FIG. 4C corresponding to FIG. 4A, P1 denotes the strength of the lens 401, and P2 denotes the strength of the lens 402, and FIG. 4C shows an example of a lens strength distribution on a beam-by-beam basis in the form of a graph. P1 is equal with respect to all the 5 lengths of the beams, while P2 varies by the beam, as described with reference to FIGS. 3A to 3C. As a result, a lens strength (P1+P2) that varies according to the distance from the center axis is imparted by the lens array 110.

Meanwhile, FIG. 4D corresponds to FIG. 4B, showing an example of a lens strength distribution on a beam-by-beam basis in the form of a graph. In FIG. 4B, the curvature of the lens array image surface (the lens array image-forming surface or the crossover image surface) to be formed is smaller, as compared with FIG. 4A. In order to implement this, the lens strength P2 in FIG. 4D is set lower than P2 in FIG. 4C. On the other hand, in order to keep the image forming position of the center beam (c) so as to be constant, the sum of the lens strengths, acting on the center beam (c), is set equal to that in FIG. 4C by setting the lens strength P1 in FIG. 4D is set higher than P1 in FIG. 4C.

Thus, the respective diameters of the openings in the second electrode (302, 401) of the lens array comprised of the four plates of the electrodes is varied in distribution from the respective diameters of the openings in the third electrode (303,402), and the voltage V1 to be applied to the second electrode 302, and the voltage V2 to be applied to the third electrode 303 are controlled as appropriate, whereupon the curvature of the lens array image surface, and the image forming position of the lens close to the center axis can be independently controlled. More specifically, in this example, the curvature of the lens array image surface (the lens array image-forming surface or the crossover image surface) is controlled by the third electrode, and V2, and the image forming position of the lens close to the center axis is controlled by the second electrode, and V1. By so doing, even in the case of changing a variety of the optical conditions (a focal distance, and so forth, with respect to other lenses of the electron beam apparatus), a lens array image surface corresponding thereto can be set as appropriate, so that it is possible to constantly minimize the curvature of field aberration on a specimen.

In the first embodiment, at the time of adjustment of the curvature of the lens array image surface (the lens array image-forming surface or the crossover image surface), the voltages V1, and V2 are controlled in such a way as to keep the image forming position of the center beam (c) to remain constant. However, since the essence of the first embodiment lies in that the two parameters, that is, the image forming position of the lens close to the center axis, and the curvature of the lens array image surface are controlled by adjusting the two voltages (V1, V2), the image forming position of the center beam (c) need not necessarily be constant, and can be adjusted to a desired value as necessary.

In the first embodiment, the respective diameters of the openings corresponding to all the beams are set identical to each other with respect to the second electrode of the lens array comprised of the four plates of the electrodes. However, the principle behind the lens array according to the first embodiment lies in the control of the lens strength distribution through independent control of respective voltages applied to the two plates of the electrodes differing from each other in terms of a distribution of the respective diameters of the openings, and therefore, only if the second electrode differs in the diameter of the opening from the third electrode, the same effect can be obtained.

Further, with the first embodiment, in order to cause the curvature of the lens array image surface (the lens array image-forming surface or the crossover image surface) to be inverted from the curvature of field of the lens provided in the downstream, that is, to be convex upward, the opening in the third electrode is formed such that the further the opening is away from the center, the larger the diameter of the opening is. However, for example, in the case where the curvature of the lens array image surface is directed so as to be convex downward, use may be made of an electrode having openings, the diameter of each of the openings decreasing in size as the opening is further away from the center. Further, if the diameter of each of the openings in, for example, the second electrode increases in size as the opening is further away from the center, and conversely, if the diameter of each of the openings in the third electrode decreases in size, contrary to the case of the second electrode, as the opening is further away from the center, this will enable the curvature of the lens array image surface to be controlled with greater accuracy.

Still further, with the first embodiment, because the lenses in the downstream are the electromagnetic lenses that are rotationally symmetrical, the curvature of field aberration as well is rotationally symmetrical. However, there can be the case where the respective curvatures of field aberration of the lenses in the downstream are not rotationally symmetrical, including the case of using a lens that is non-rotationally symmetrical, such as a quadrupole lens, an octupole lens, and so forth. In such a case, the same effect can be obtained by varying the distribution of the respective diameters of the openings, in the lens array, according to respective azimuths instead of varying the same according to only the distance from the center axis. Further, with the first embodiment, adjustment of the respective magnifications of the objective lenses 116a, 116b is intended, and a scheme for correcting a change in the curvature of field aberration, accompanying the adjustment, is described. However, even in the case of intending to change energy of the primary beam falling on a specimen, and in the case of intending to change the intensity of an electric field in the vicinity of a specimen surface, the first embodiment is effective as a unit for correcting a change in the curvature of field aberration, accompanying those actions.

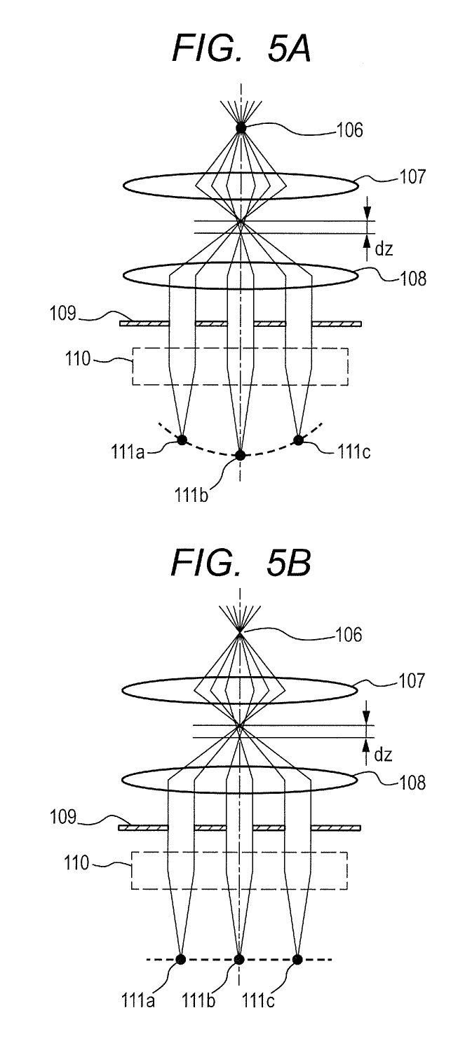

Furthermore, the scheme for controlling the curvature of the lens array image surface (the lens array image-forming surface or the crossover image surface) according to the first embodiment is effective as a unit for correcting a spherical aberration in the lenses in the upstream of the lens array. This is described with reference to FIGS. 5A and 5B.

The spherical aberration is a phenomenon in which a beam on a track departing from a point on an optical axis does not form an image at one point on an image surface. FIG. 5A is a view showing a relationship between the spherical aberration of the condenser lens 107 and the curvature of the lens array image surface (the lens array image-forming surface or the crossover image surface), by the agency of the lens array 110. The beam close to the center axis and the beams away from the center axis, among the beams traveling from the crossover 106, form respective images at locations differing from each other by dz due to the spherical aberration. As a result, if the collimator lens 108 and the lens array 110 impart an equal convergence action to all the beams, the lens array image surface formed by multiple crossover images 111a, 111b, and 111c will end up in a curved surface that is convex downward as indicated by a dotted line. Accordingly, in FIG. 5B, a lens strength distribution in the lens array 110 is adjusted so as to cancel out the effect of the difference in the image forming position, caused by the spherical aberration of the condenser lens 107. A method for such adjustment is the same as the method described with reference to FIGS. 4A to 4D. As a result, the lens array image surface can be formed planar in shape, as indicated by a dotted line.

Further, in FIGS. 5A and 5B, the correction of the spherical aberration of the condenser lens is described, however, the correction can be similarly executed with respect to optical elements in the upstream of the lens array, other than the condenser lens, such as the electron gun 101, the magnetic field superimposing lens 104, the collimator lens 108, and so forth. Accordingly, even if the respective optical conditions of the lenses in the upstream of the lens array, for example, the acceleration voltage of the electron gun, and the magnification of the lens are changed, the curvature of the lens array image surface (the lens array image-forming surface or the crossover image surface) can be always adjusted to a desired value in the case of the first embodiment, so that it is possible to expand a setting width of the optical condition.

### <Method for Setting an Optical Condition in the Electron Beam Apparatus>

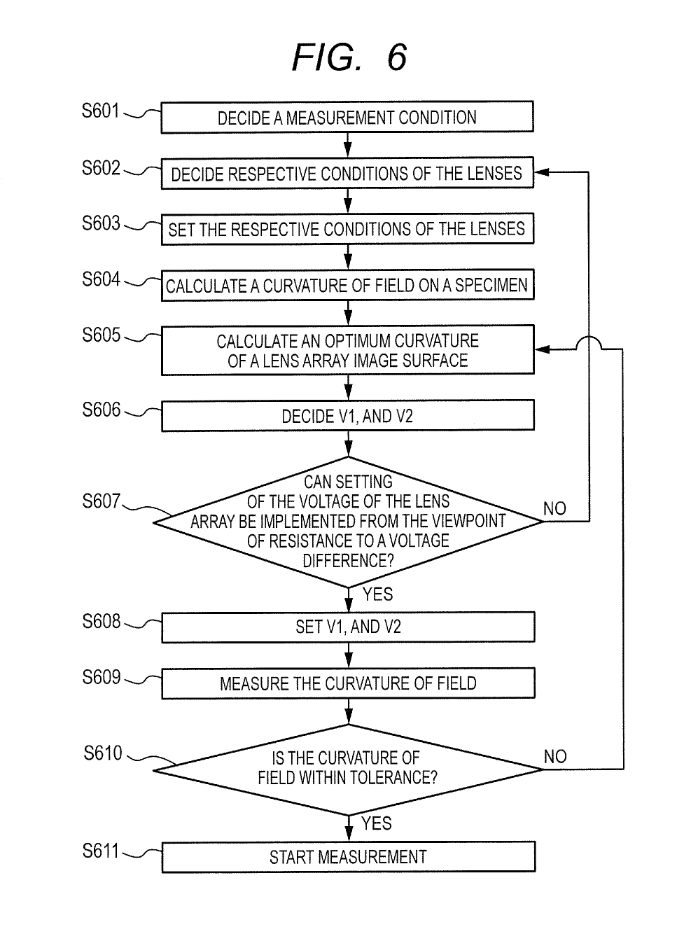

Next, a procedure for setting an optical condition of the electron beam apparatus according to the first embodiment is described with reference to the example of the schematic configuration shown in FIG. 1, and an example of a flow chart shown in FIG. 6. In step S601, an operator inputs a measurement condition via the input unit 133, or selects a combination of preset measurement conditions through selection from a menu including “high speed mode”, “high resolution mode”, and so forth. The measurement condition represents, for example, the current of a beam with which a specimen is irradiated, incident energy, the intensity of an electric field in the vicinity of a specimen surface, and so forth.

In step S602, the measuring-condition setting program 132 installed in the system control unit 128 decides parameters of the respective optical elements on the basis of the measurement condition set in the step S601. The parameters include, for example, the magnification of the condenser lens 107, the focal distance of the collimator lens 108, the respective magnifications of the transfer lenses 113a, 113b, the respective magnifications of the objective lenses 116a, 116b, the voltage applied to the surface electric field control electrode 119, the focal distance of the electromagnetic lens 123, and so forth. Further, the parameters include the acceleration voltage of the electron gun, both a current and a voltage that are applied to the Wien filter 114, and so forth.

In step S603, the optical system control circuit 134 sets voltage•current to be applied to the respective optical elements on the basis of the parameters set in the step S602, under control of the measuring-condition setting program 132.

In step S604, the measuring-condition setting program 132 refers to a relationship between pre-inputted magnifications of the respective lenses, and curvatures of field thereof, thereby calculating a curvature of field on the specimen 120, predicated on the precondition of the parameters set in the step S602.

In step S605, the measuring-condition setting program 132 calculates an optimum curvature of the lens array image surface (the lens array image-forming surface or the crossover image surface). More specifically, the measuring-condition setting program 132 converts the curvature of field on the specimen 120, found in the step S604, into a curvature of field of the lens array 110 on the basis of respective longitudinal magnifications of the transfer lenses 113a, 113b, and respective longitudinal magnifications of the objective lenses 116a, 116b.

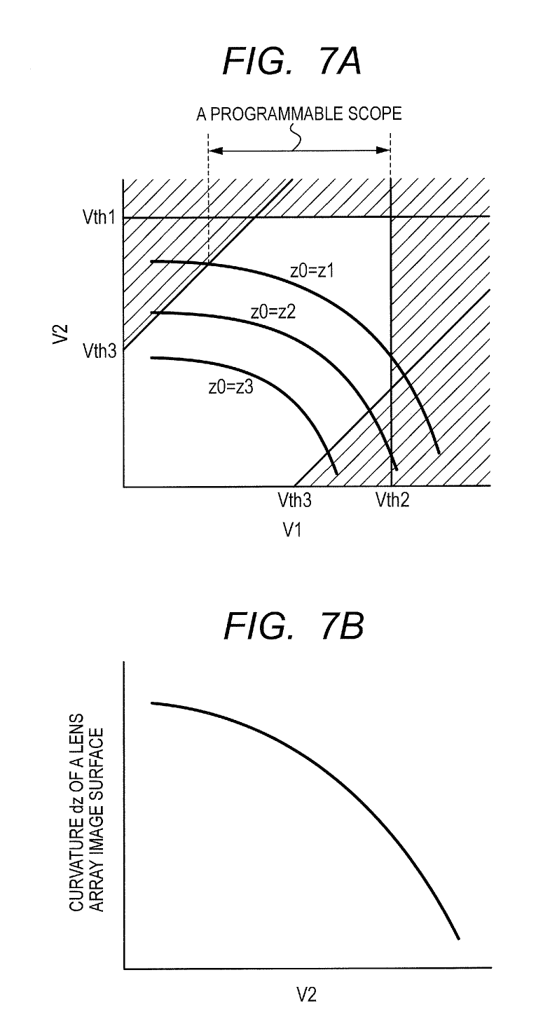

In step S606, the measuring-condition setting program 132 decides the voltage V1 to be applied to the second electrode of the lens array 110, and the voltage V2 to be applied to the third electrode of the lens array 110, as shown in FIGS. 3A to 3C, and so forth. Herein, a method for deciding V1 and V2 is described with reference to FIGS. 7A and 7B.

FIG. 7A shows a relationship between an image forming position z and the respective voltages V1, V2, against a reference beam among the plurality of the beams, and the relationship can be found by actual measurement, or optical calculation. In this case, a beam on the center axis, corresponding to, for example, the center beam (c) in FIG. 4A, is defined as the reference beam. If a beam is not disposed on the center axis, a beam closest to the center axis may be defined as the reference beam. Since the diameter of the opening in the respective electrodes of the lens array 110, passed by the reference beam, is fixed, a relationship between V1 and V2 with respect to a desired image forming position z can be uniquely decided using a graph shown in FIG. 7A. Meanwhile, FIG. 7B is a graph showing a relationship between the curvature of the lens array image surface (the lens array image-forming surface or the crossover image surface) and V2, predicated on the precondition of the relationship between V1 and V2, fixed in FIG. 7A. The graph indicates that V2 is uniquely decided against a desired curvature. More specifically, it is evident that if the image forming position z of the reference beam, and a desired value of the curvature dz of the lens array image surface are found, V1, and V2 are uniquely decided.

In step S607, the measuring-condition setting program 132 determines whether or not setting of the voltage of the lens array 110 can be implemented from the viewpoint of resistance to a voltage difference. The lens array is comprised of the four plates of the electrodes, as previously described, and various voltages are applied to the respective electrodes, thereby causing occurrence of a lens action. An insulating member is sandwiched between the adjacent electrodes in the four plates of the electrodes, and if a voltage difference exceeds a predetermined value, this will raise the risk that an electrical discharge occurs to thereby impair the function of the lens, and break down the lens array, or a power supply. Accordingly, it is necessary to impose a limitation to the respective absolute values of the voltages V1, V2 and a voltage difference between the voltages V1 and V2.

For example, a diagonally shaded region in FIG. 7 A is a region not suitable for setting of the voltages from the viewpoint of the resistance to the voltage difference, described as above. Accordingly, in the step S607, the measuring-condition setting program 132 determines whether or not the voltages V1, V2, decided in the step S606, are found within a programmable scope. If the measuring-condition setting program 132 determines that V1, V2 are in the programmable scope, processing proceeds to step S608. If it is determined that V1, V2 are not in the programmable scope, the processing reverts to the step 602 to thereby change part of the lens condition such that V1, V2 are caused to fall in the programmable scope, thereby re-deciding all the lens condition. For example, the image forming position z of the reference beam in the lens array 110 may be changed, or the optimum curvature of the lens array image surface (the lens array image-forming surface or the crossover image surface) may be changed by changing the condition of the lens other than the lens array.

In step the S608, the optical system control circuit 134 sets the voltage V1, and the voltage V2, decided in the step 606, to the second electrode of the lens array 110, and the third electrode of the lens array 110, respectively, under control of the measuring-condition setting program 132.

In step S609, the electron beam apparatus measures the image forming position with respect to the respective beams under control of the measuring-condition setting program 132, thereby measuring the curvature of field on the specimen 120. A calibration mark (not shown in FIG. 1) for checking the shape of a beam is provided on, for example, the stage 121, and the image forming position on a beam-by-beam basis is found using the calibration mark. More specifically, the beam is caused to scan over the calibration mark, while varying a current applied to the objective lens 116b, thereby seeking a current value of the objective lens generating a secondary beam signal high in contrast. If this is repeated on a beam-by-beam basis, an optimum current value of the objective lens can be found on the beam-by-beam basis. Because a relationship between the current value of the objective lens and a height of the specimen can be found in advance using multiple the calibration marks differing in height from each other, the curvature of field on the specimen can be found from a difference between the respective current values of the objective lens against the beam close to the center axis, and the beam away from the center axis.

In step S610, the measuring-condition setting program 132 determines whether or not the curvature of field measured in the step S609 is within tolerance. If it is determined that the curvature of field is outside the tolerance, the processing reverts to the step 605, thereby re-calculating the optimum curvature of the lens array image surface (the lens array image-forming surface is or the crossover image surface). If it is determined that the curvature of field is within the tolerance, this indicates completion of the setting of the optical condition, whereupon measurement of the specimen 120 is started in step S611.

Adoption of the flow chart described as above enables the correction of the curvature of field aberration to be executed so as to correspond to various optical conditions. Furthermore, in this case, protection of the lens array can be achieved by taking the resistance to the voltage difference with respect to the lens array 110 into consideration, and the correction of the curvature of field aberration can be implemented with higher precision by verifying whether or not the respective voltages V1, V2 of the lens array are appropriate on the basis of actual measurement of the curvature of field on the specimen 120. In this case, the measurement of the image forming position, in the step 609, is executed using the calibration mark provided on the stage 121; however, a beam detection unit may be installed at another position in the case where measurement with higher sensitivity is required, and so forth. For example, if an aperture having a sharp end face is provided in the vicinity of the lens array image surface, and the beam having scanned over the aperture is detected by a detector such as a photodiode, a Faraday cup, and so forth, a beam shape on the aperture can be measured by a knife-edge method.

According to the present embodiment, various explanations are given hereinabove on the assumption that the electron beam measuring apparatus is one example of the electron beam apparatus, however, the present invention can be similarly applied to all the apparatuses having an electron optical system using a lens array capable of causing multiple beams to be individually converged, thereby obtaining the same advantageous effects. More specifically, the invention can be applied to, for example, an inspection apparatus for examining the presence or absence of a defect in a pattern formed on a specimen, an electron microscope such as a review SEM for observing a defect in a pattern formed on a specimen, and so forth. Furthermore, the invention can be applied to, for example, an electron bean imaging apparatus with an electron microscope applied thereto.

### Second Embodiment

### <Lens Array in Detail (Variation [1])>

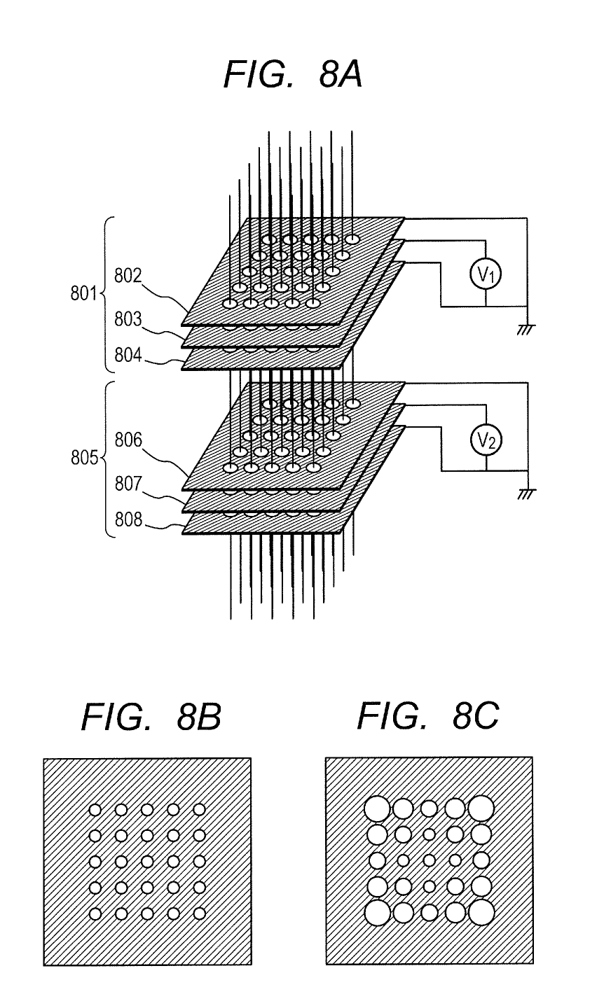

FIGS. 8A to 8C each are a schematic representation showing an example of the configuration of a lens array in an electron beam apparatus according to a second embodiment of the invention. The lens array shown in FIG. 8A is comprised of two units of lens arrays, including a first lens array 801, and a second lens array 805. The first lens array 801 is comprised of 3 plates of electrodes, including a first electrode 802, a second electrode 803, and a third electrode 804, provided in this order from the upstream side (a side of the lens array, adjacent to an electron gun). The respective electrodes have 25 pieces of openings formed therein. The respective openings are circular in shape, and the respective openings in each of the electrodes are disposed such that a beam axis of each of 25 lengths of beams, indicated by a solid line in the figure, penetrates through the center of the opening. A common voltage (in this case, the ground voltage) is connected to the first electrode 802, and the third electrode 804, respectively, and a voltage V1 from a power supply is supplied to the second electrode 803.

The second lens array 805 as well is comprised of 3 plates of electrodes, including a first electrode 806, a second electrode 807, and a third is electrode 808, provided in this order from the upstream side (the side of the lens array, adjacent to the electron gun). The respective electrodes have 25 pieces of openings formed therein. The respective openings are circular in shape, and the respective openings in each of the electrodes are disposed such that a beam axis of each of the 25 lengths of the beams, indicated by a solid line in the figure, penetrates through the center of the opening. A common voltage (in this case, the ground voltage) is connected to the first electrode 806, and the third electrode 808, respectively, and the voltage V1 from the power supply is supplied to the second electrode 807.

FIG. 8B shows the diameter of each of the openings in the respective electrodes composing the first lens array 801, and a layout of the openings, while FIG. 8C shows the diameter each of the openings in the respective electrodes composing the second lens array 805, and a layout of the openings. In contrast to the respective diameters of the 25 openings in the respective electrodes of the first lens array 801 being all equal, as shown in FIG. 8B, the respective openings in each of the electrodes of the second lens array 805 are formed such that the further away the opening is, the greater the diameter of the opening is, as shown in FIG. 8C.

This configuration example can be regarded as a configuration of a lens array, made up by splitting the lens array shown in FIGS. 3A to 3C into two, at an interface between the second electrode 302 and the third electrode 303, thereby adding one plate each of an electrode at the ground voltage to the most downstream side, and the most upstream side of the lens array, respectively. In this case, the lens strength of each of the two lens array units is dependent on the voltage V1 applied to the second electrode 803 of the first lens array 801, and the voltage V2 applied to the second electrode 807 of the second lens array 805. Accordingly, the curvature of the lens array image surface (the lens array image-forming surface or the crossover image surface) can be controlled, as is the case with the first embodiment.

The merit of the lens array being split into the two units lies in that an aligner (not shown) can be installed between the two lens array units. More specifically, the track of the beam can be corrected even in the case where misalignment occurs at the time of assembling the two lens array units with each other, so that the plurality of the beams can be excellently converged.

### Third Embodiment

### <Lens Array in Detail (Variation [2])>

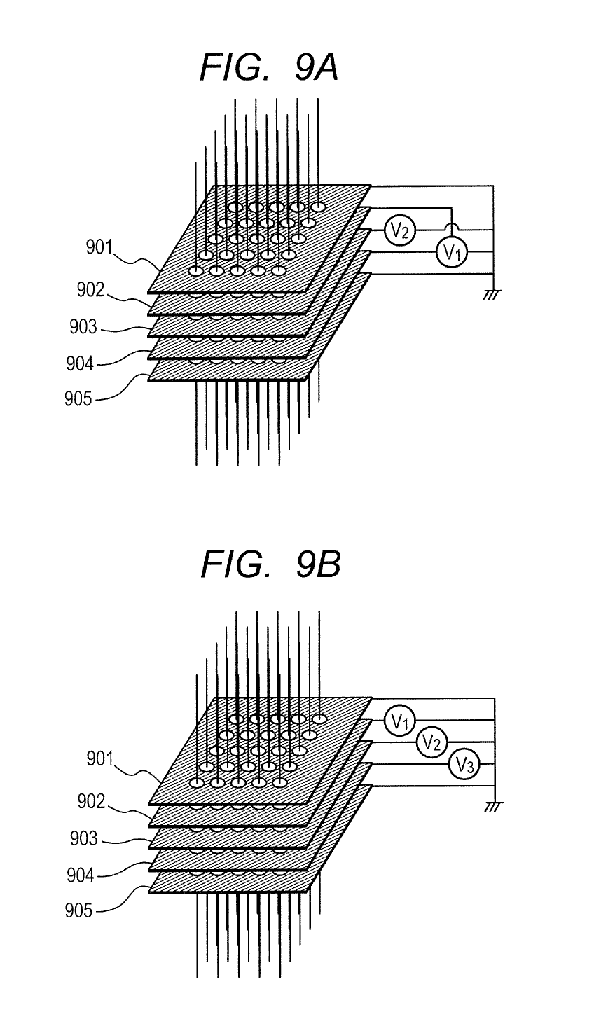

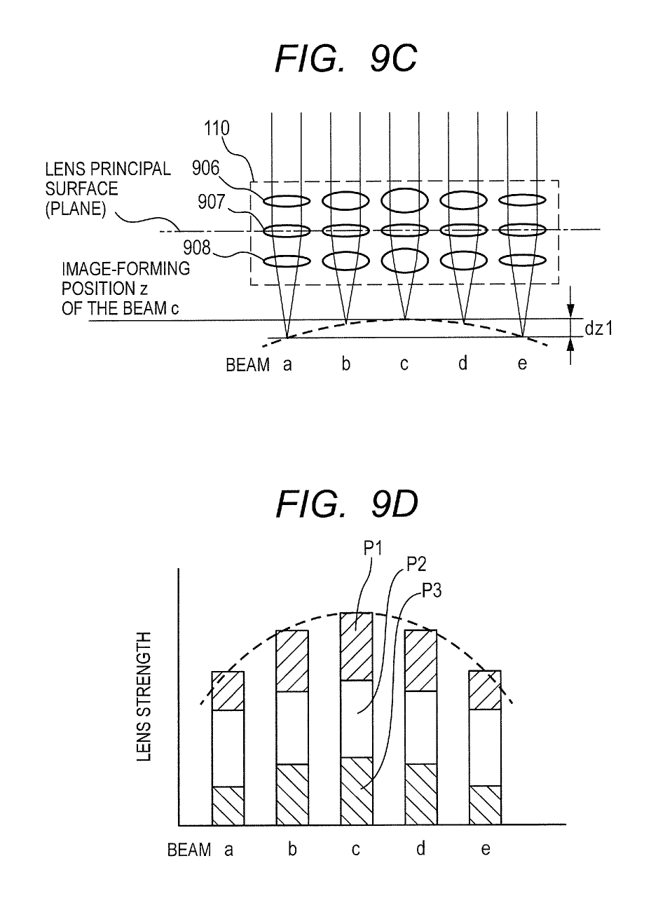

FIG. 9A is a schematic representation showing an example of the configuration of a lens array in an electron beam apparatus according to a third embodiment of the invention. The lens array shown in FIG. 9A is comprised of 5 plates of electrodes, including a first electrode 901, a second electrode 902, a third electrode 903, a fourth electrode 904, and a fifth electrode 905, provided in this order from the upstream side (a side of the lens array, adjacent to an electron gun). The lens array of FIG. 9A is made up so as to be vertically symmetrical about the third electrode 903, and an interval between the first electrode 901 and the second electrode 902 is equal to an interval between the fourth electrode 904 and the fifth electrode 905. Further, an interval between the second electrode 902 and the third electrode 903 is equal to an interval between the third electrode 903 and the fourth electrode 904. Multiple openings, each thereof being circular in shape, are disposed in each of the electrodes such that the beam axis of each of 25 lengths of beams, indicated by a solid line in the figure, penetrates through the center of the opening.

The respective diameters of 25 pieces of the openings are all equal with respect to the first, third, and fifth electrodes (901, 903, 905, respectively, as is the case with the configuration example shown in FIG. 3B. On the other hand, the openings with respect to the second electrode, and the fourth electrode (902, 904), respectively, are formed such that the further the opening is away from the center of an array, the larger the diameter of the opening is, as is the case with the configuration example shown in FIG. 3C. The second electrode is identical in respect of the diameter of the opening to the fourth electrode. A common voltage (in this case, the ground voltage) is applied to the first electrode 901, and the fifth electrode 905, respectively, while a power supply is independently connected to the second electrode 902, the third electrode 903, and the fourth electrode 904, respectively. The voltage of the second electrode 902 is V1, the voltage of the third electrode 903 is V2, and the voltage of the fourth electrode 904 is identical to the voltage V1 of the second electrode 902.

Next, referring to FIGS. 9C, and 9D, there is described a scheme for controlling the curvature of the lens array image surface (the lens array image-forming surface or the crossover image surface) in the lens array shown in FIG. 9A. FIG. 9C is a schematic diagram showing the respective tracks of 5 lengths of beams at various distances from the center axis in the case where the curvature of the lens array image surface (the lens array image-forming surface or the crossover image surface) is adjusted such that a difference in the image forming position between a center beam (c) and a beam (a) away from the center axis is dz1. The lens array of FIG. 9A is comprised of the 5 plates of the electrodes; however, because a lens strength can be adjusted by the respective is voltages applied to the second, third, and fourth electrodes (902, 903, and 904), the lens array can be approximated to a composition of lenses in three stages. In FIG. 9C, there are shown these lenses in the three stages, including a lens 906 whose strength is decided by the voltage V1 of the second electrode, a lens 907 whose strength is decided by the voltage V2 of the third electrode, and a lens 908 whose strength is decided by the voltage V1 of the fourth electrode.

FIG. 9D corresponds to FIG. 9C, showing a lens strength distribution on a beam-by-beam basis in the form of a graph on the assumption that P1 denotes the strength of the lens 906, P2 the strength of the lens 907, and P3 the strength of the lens 908.

Since the openings in the second electrode (902) are formed such that the further the opening is away from the center of the array, the larger the diameter of the opening is, as described with reference to FIG. 9A, P1 varies by the beam. Since the lens array is made up so as to be vertically symmetrical about the third electrode 903, P3 is always equal to P1. Meanwhile, the openings formed in the third electrode (903) are all equal against all the beams, and therefore, P2 is equal against all the 5 lengths of the beams.

With the third embodiment of the invention, as well, the two parameters, that is, the image forming position of the lens close to the center axis, and the curvature of the lens array image surface (the lens array image-forming surface or the crossover image surface) can be independently controlled by adjusting the two voltages (V1, V2), as is the case with the first embodiment. With the third embodiment of the invention, in addition to this, a lens principal plane can be independently controlled. Herein, the lens principal plane represents the center of gravity of lens strength on a track passed by one length of a beam. Variation of the lens principal plane will cause variation in a beam spread angle on the image surface, whereupon defocusing (aberration) of a beam undergoes variation, thereby raising the risk of causing variation in the diameter of the beam, on the specimen. Meanwhile, with the third embodiment of the invention, because the lens array is made up so as to be vertically symmetrical about the third electrode 903, as shown in FIG. 9C, the lens principal plane is formed at a position of the lens 907 (the third electrode) as indicated by a dash and dotted line. Because this symmetry will hold regardless of any of V1, and V2, it can be said that the lens principal plane can always be kept constant even in the case where the image forming position of the lens close to the center axis, and the curvature of the lens array image surface are changed.

Further, in FIG. 9A, the openings in the second electrode 902, and the fourth electrode 904, respectively, are formed such that the further the opening is away from the center of the array, the larger the diameter of the opening is, and the openings formed in the third electrode 903 are set so as to be equal against all the beams. However, contrary to the above, even if the respective diameters of the openings in the second electrode 902, and the fourth electrode 904, respectively, are set so as to be equal against all the beams, and the openings in the third electrode 903 are set such that the further the opening is away from the center of the array, the larger the diameter of the opening is, an equivalent result can be obtained.

Further, the principle behind the present embodiment lies in that respective voltages applied to the two plates of the electrodes differing from each other in terms of distribution of the respective diameters of the openings are independently controlled in the lens array having a vertically symmetrical structure, thereby controlling the lens strength distribution, and therefore, only if the second electrode is identical in the diameter of the opening to the fourth electrode, and the third electrode differs in the diameter of the opening from both the second and fourth electrodes, the same effect can be obtained.

Further, the essence of the present embodiment lies in that the lens principal plane is always kept constant, so that even if the second electrode differs in electrode diameter from the fourth electrode, the same effect can be obtained provided that the lens strength distribution shown in FIG. 9D can be formed by voltage control. More specifically, even if the second electrode differs in the electrode diameter from the fourth electrode, and the structure is not vertically symmetrical, it need only be sufficient to have the lens strength distribution that is rendered vertically symmetrical as shown in FIG. 9C by virtue of voltage control. In this case, it is necessary that voltages V1, V2, V3 from individual power supplies are applied to the second electrode 902, the third electrode 903, and the fourth electrode 904, respectively, as shown in FIG. 9B.

With the present embodiment, the lens array is made up in order to cause the lens principal plane to be kept constant against all the beams. However, if the voltages V1, V2, V3 to be applied to the second electrode 902, the third electrode 903, and the fourth electrode 904, respectively, are individually controlled, as shown in FIG. 9B, this will enable more flexible control of the lens principal plane. More specifically, the lens principal plane can be formed in a curved surface as desired.

### Fourth Embodiment

{Gist of a Scheme for Correction of the Curvature of Field Aberration (Application Example [1])}

In the respective cases of the first, and second embodiments described hereinabove, the curvature of field aberration as the target of correction is static, that is, is constant time-wise, and accordingly, the voltage applied to the lens array is a DC voltage which is constant time-wise too. With a fourth embodiment of the invention, dynamic correction of a change in the curvature of field aberration, accompanying scanning over a specimen, with the beam. In this case, explanation is given by taking the electron measuring apparatus as an example of the electron beam apparatus, as is the case with the first embodiment, however, it is to be pointed out that the invention is particularly effective in both the electron beam inspection apparatus, and the electron beam exposure apparatus, having a wide beam scanning scope on a specimen.

In this case, scanning over a specimen 120, with a beam, is executed by the deflector 117 installed inside the objective lens 116a, 116b, as described in the first embodiment, with reference to FIG. 1.

Upon a scan-signal generated from the scan-signal generation circuit 135 being inputted to the deflector 117, substantially uniform deflection electric fields are formed in the deflector, and the primary beams passing through the deflector are deflected. At this point in time, a deflection curvature of field aberration, and a hybrid curvature of field aberration are included in an aberration occurring as a result of deflection. Because the deflection curvature of field aberration, among those aberrations, occurs in common with all the beams, there is provided a dynamic focus lens (not shown) that acts in common with all the beams of the projection optical system, and a voltage or a current is supplied thereto in sync with the deflection, whereupon the deflection curvature of field aberration can be corrected. On the other hand, the hybrid curvature of field aberration is decided by both a position vector, and a deflection vector, so that the hybrid curvature of field aberration cannot be corrected by the dynamic focus lens. Accordingly, with the fourth embodiment of the invention, a voltage in sync with the deflection is supplied to the lens array, thereby executing the dynamic correction of the curvature of field aberration.

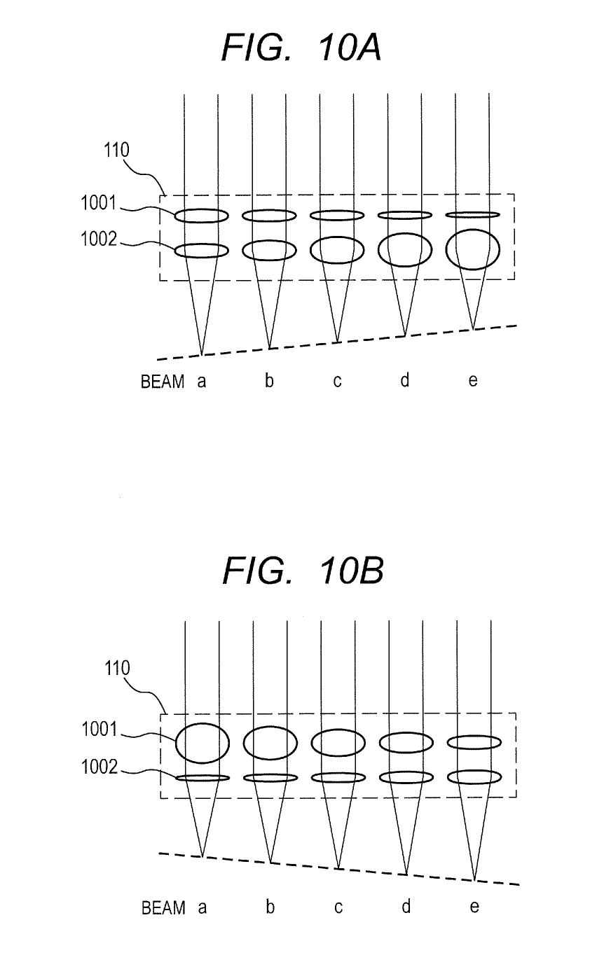

Herein, the principle behind the correction of the hybrid curvature of field aberration is described hereinafter. The hybrid curvature of field aberration can be represented by a formula A×M×R×cos(α−θ+φ) where R=a distance between the primary beam and the center beam, θ=an azimuth, M=a deflection distance, φ=an azimuth, A=the absolute value of a hybrid curvature of field aberration, and α=an azimuth. In this case, the hybrid curvature of field aberration will be at the maximum if α−θ+φ=0, will be zero if α−θ+φ=90°, and will be at the minimum if α−θ+φ=180°. If the case of the azimuth α=zero is assumed for brevity, the curvature of field aberration will be at the maximum when the position vector of a beam, and the deflection vector thereof are oriented in the same direction, while the curvature of field aberration will be at the minimum when the position vector of the beam, and the deflection vector thereof are oriented in directions opposite from each other. If a lens array image surface (a lens array image-forming surface or a crossover image surface) is tilted as shown in FIG. 10A, this will suffice for correcting this.

In FIG. 10A, the convergence action of a lens array 110 is expressed by lenses in two stages. Reference numeral 1001 denotes a lens whose strength is decided by the voltage V1 of the second electrode, and 1002 denotes a lens whose strength is decided by the voltage V2 of the third electrode. In this case, the lens 1001 whose strength increases in stages toward one direction, and the lens 1002 whose strength increases in stages toward a direction opposite from the one direction are provided, and a balance between the respective average strengths of the two lenses is controlled by the respective voltages V1, V2, thereby tilting the lens array image surface (the lens array image-forming surface or the crossover image surface). Further, in normal scanning with a beam, the primary beam undergoes lateral or vertical deflection, and therefore, there is the need for tilting the lens array image surface in a reverse direction, as shown in FIG. 10B, against the deflection toward a direction opposite from that in the case of FIG. 10A.

### <Lens Array in Detail (Application Example [1])>

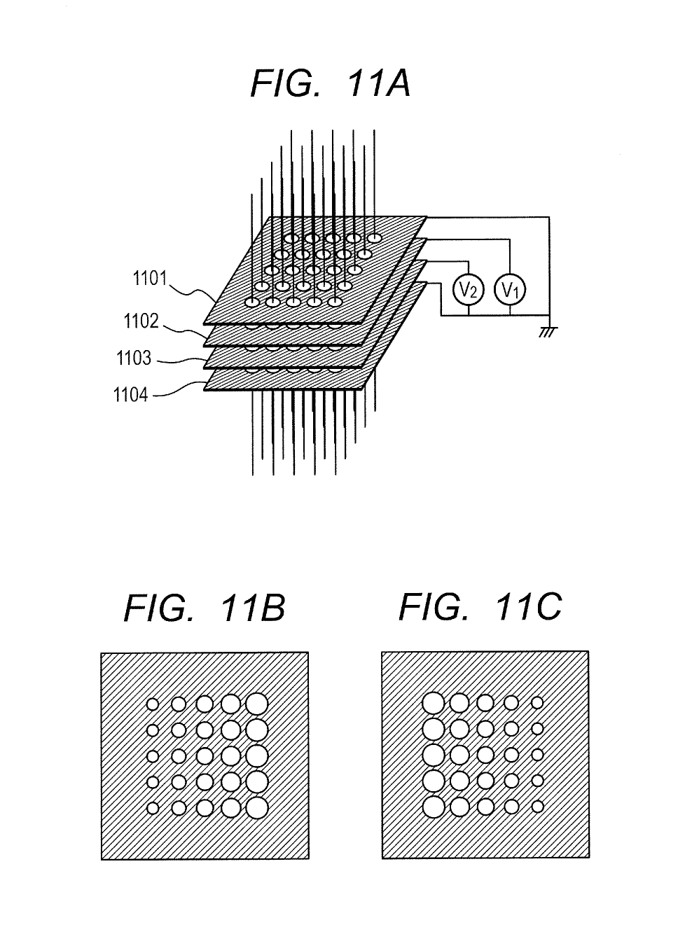

FIGS. 11A to 11C each are a schematic representation showing an example of the configuration of the lens array in the electron beam apparatus according to the fourth embodiment of the invention. The configuration of the lens array, described with reference to FIGS. 11A to 11C, is preferably adopted in order to implement the dynamic correction of the curvature of field aberration, as previously described. The lens array shown in FIG. 11A is comprised of four plates of electrodes, having a first electrode 1101, a second electrode 1102, a third electrode 1103, and a fourth electrode 1104, provided in this order from the upstream side (the side of the lens array, adjacent to the electron gun), as is the case with the first embodiment. A common voltage (in this case, the ground voltage) is applied to the first electrode 1101, and the fourth electrode 1104, respectively, while a power supply is independently connected the second electrode 1102, and the third electrode 1103, respectively. The voltage of the second electrode 1102 is V1, and the voltage of the third electrode 1103 is V2.

The respective diameters of 25 pieces of the openings are all equal with respect to the first, and fourth electrodes (1101, 1104), respectively, as is the case with FIG. 3B. On the other hand, if a deflection direction is from the left to the right on the plane of the figure, the respective diameters of the openings in the second electrode 1102 increase in size in stages rightward on the plane of the figure, as shown in FIG. 11B. Conversely, the respective diameters of the openings in the third electrode 1103 increase in size in stages leftward on the plane of the figure, as shown in FIG. 11C. A signal in sync with the scan-signal is inputted to the second and third electrodes (1102, 1103) of the lens array described as above. More specifically, the respective voltages V1, V2 are controlled in sync with the lateral deflection of the primary beam. Because V1, V2 can act so as to bidrectionally tilt the lens array image surface (the lens array image-forming surface or the crossover image surface) as shown in FIGS. 10A, 10B, a control is executed such that V1 is rendered greater than V2 according to the deflection direction, or a control in an opposite phase is executed such that V2 is conversely rendered greater than V1. With the use of such a method as described, the correction of the curvature of field aberration can be executed regardless of a deflection position.

With the fourth embodiment of the invention, there has been described only the correction of the curvature of field aberration, accompanying the scanning over a specimen, with the beam, however, in reality, if the correction of the static curvature of field aberration described in the first to the third embodiments, respectively, or the correction of the deflection curvature of field aberration, using dynamic focus lens is combined with the former, this will enable a curvature of field aberration to be more suitably corrected. More specifically, for example, the lens array shown in FIG. 3A, and so forth can be disposed in a part of the lens array 110 of FIG. 1, and the lens array shown in FIG. 11A can be disposed at an upper part, or a lower part in the direction of the beam axis, or the lens array shown in FIG. 3A, and so forth can be disposed, and the electrodes shown in FIGS. 11B, 11C, respectively, can be inserted between the uppermost and lowermost electrodes of the lens array in some cases.

### Fifth Embodiment

### {Gist of a Scheme for Correction of the Curvature of Field Aberration (Application Example [2])}

With a fifth embodiment of the invention, there is described an example in which the scheme for controlling the curvature of the lens array image surface (the lens array image-forming surface or the crossover image surface), as described in the foregoing, is applied to a reflection electron-beam imaging apparatus. The reflection electron-beam imaging apparatus is an imaging apparatus where electron beams in a shape corresponding to a pattern to be rendered are reflected using a reflecting mirror capable of controlling reflection/absorption on a pixel-by-pixel basis, and the electron beams each are focused in reduced size, thereby rendering a desired pattern on a wafer. The reflecting mirror is provided with an array of micro-electrodes, thereby controlling reflection/absorption on the pixel-by-pixel basis by controlling voltages applied to the respective micro-electrodes.

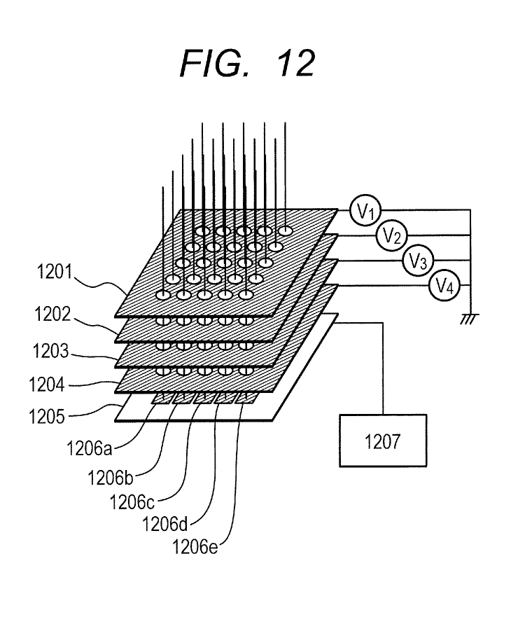

FIG. 12 is a schematic diagram showing an example of the construction of the reflecting mirror included in an electron beam apparatus according to the fifth embodiment of the invention. In FIG. 12, incident beams travel downward from above in the plane of the figure, and only the beams from among the incident beams, corresponding to pixels to be rendered, respectively, are reflected by the reflecting mirror to be returned upward from below in the plane of the figure. Further, only 25 lengths of the beams are depicted in FIG. 12, for brevity, however, needless to say, numerous lengths of the beams are required in order to implement high-speed rendering.

More specifically, the reflecting mirror is comprised of a lens array, and respective units of a pattern generator 1205, as shown in FIG. 12, and the lens array is made up of four plates of lens electrodes 1201 to 1204, piled up with an insulator (not shown) sandwiched between the lens electrodes adjacent to each other. The lens electrodes 1201 to 1204 each are provided with openings formed around respective tracks of incident beams, indicated by a solid line in the figure, respectively, an independent voltage being applied to the respective openings. The pattern generator 1205 is provided with micro-electrodes corresponding to the respective beams. Herein, there are shown the micro-electrodes 1206a, 1206b, 1206c, 1206d, and 1206e, representing only a portion of the micro-electrodes.

A positive voltage or a negative voltage, according to the pattern to be rendered, is applied to the respective micro-electrodes. If a negative voltage greater in energy than the incident beam is applied, the incident beam is reflected. Conversely, if a positive voltage is applied, the incident beam is absorbed by the micro-electrode. Voltages applied to the respective micro-electrodes are controlled by a pattern-generator control circuit 1207. Reflected beams reach onto a wafer via a contraction optical system (not shown) is provided on an upper side in plane of the figure.

Even with the electron beam apparatus of such a reflection type described as above, the curvature of field aberration can pose a problem. More specifically, the beam reflected by the reflecting mirror has an areal spread, the image forming position of the beam passing through the track close to the center axis, on the wafer, ends up differing from that of the beam passing through the track away from the center axis, due to the curvature of field aberration of the contraction optical system, at the time when the electron beams each are focused in reduced size on the wafer. With the fifth embodiment of the invention, the respective diameters of the openings in any one of the lens electrodes 1202, 1203, 1204 are set so as to vary according to a distance from the center axis of the contraction optical system in order to prevent occurrence of such a situation described as above. Further, the image forming position of the beam close to the center axis, and the curvature of the lens array image surface are independently controlled by controlling respective voltages applied to the lens electrodes 1201 to 1204.

Having specifically described the invention developed by the inventor, et al. with reference to the embodiments, as above, it is our intention that the invention be not limited thereto, and that various changes and modifications may be made in the invention without departing from the spirit and scope thereof.

What is claimed is:

1. An electron beam apparatus comprising:
an electron source;
an electron gun that accelerates electrons emitted from the electron source;
an irradiation optical system that shapes up a spread of an electron beam ejected from the electron gun;
an aperture array that splits the electron beam shaped up by the irradiation optical system into a plurality of the electron beams;
a lens array that individually converges the plural electron beams split by the aperture array, thereby forming a plurality of crossover images;
a projection optical system that projects the plural crossover images formed by the lens array on a specimen; and
an optical system adjustment unit that changes a parameter of the irradiation optical system, or the projection optical system,
wherein the lens array has an image surface adjustment unit that adjusts the shape of a crossover image surface formed by the plural crossover images formed by the lens array in response to a change in the parameter, effected by the optical system adjustment unit.

2. The electron beam apparatus according to claim 1, wherein the image surface adjustment unit independently controls an image forming position of one of the crossover image among the plural crossover images, serving as a reference of the plural crossover images, and a curvature of the crossover image surface.

3. The electron beam apparatus according to claim 2, wherein the image surface adjustment unit adjusts the curvature of the crossover image surface such that a curvature of an image-forming surface projected on the specimen by the projection optical system is minimized.

4. The electron beam apparatus according to claim 2,
wherein the lens array comprises an upper electrode, a first electrode, a second electrode, and a lower electrode, sequentially disposed in an extension direction of a reference axis,
wherein first and second voltages are independently applied to the first electrode and the second electrode, respectively,
wherein a plurality of openings for permitting the plural electron beams to pass therethrough, respectively, are formed in the upper electrode, the first electrode, the second electrode, and the lower electrode, respectively,
wherein the plural openings corresponding to at least a portion of the plural electron beams, in the first electrode, differs in opening diameter from the second electrode, and
wherein the plural openings formed in at least one of electrode selected from the first electrode, and the second electrode have not less than two types of opening diameters.

5. The electron beam apparatus according to claim 4,
wherein the plural openings formed in either one electrode of the first electrode, and the second electrode have not less than two types of opening diameters, and
wherein the plural openings formed in the other electrode of the first electrode, and the second electrode have one type of opening diameter.

6. The electron beam apparatus according to claim 3, wherein the image surface adjustment unit further has a principal plane control unit for keeping a principal plane of the lens array at a predetermined location.

7. The electron beam apparatus according to claim 6,
wherein the lens array comprises an upper electrode, first electrode, a second electrode, and a lower electrode, sequentially disposed in the extension direction of the reference axis,
wherein a first voltage in common use is applied to the first electrode, and the third electrode, respectively, a second voltage independent from the first voltage is applied to the second electrode,
wherein the plurality of openings for permitting the plural electron beams to pass therethrough, respectively, are formed in the upper electrode, the first electrode, the second electrode, and the lower electrode, respectively,
wherein the plural openings corresponding to the plural electron beams, respectively, formed in the first electrode, are identical in opening diameter to the third electrode,
wherein the plural openings corresponding to at least a potion of the plural electron beams, formed in the second electrode, differs in opening diameter from the first and third electrodes, and
wherein the plural openings formed in an electrode on at least one side between the second electrode and the first and third electrodes have not less than two types of opening diameters.

8. The electron beam apparatus according to claim 4, wherein a housing voltage of the electron beam apparatus, in common use, is applied to the upper electrode, and the lower electrode, respectively.

9. The electron beam apparatus according to claim 1, further comprising a deflector for executing deflection at the time of the projection optical system projecting the plurality of the crossover images on the specimen,
wherein the image surface adjustment unit adjusts the shape of the crossover image surface in sync with a signal for controlling the deflector.

10. The electron beam apparatus according to claim 9,
wherein the lens array comprises an upper electrode, a first electrode, a second electrode, and a lower electrode, sequentially disposed in the extension direction of the reference axis,
wherein a first voltage and a second voltage are independently applied to the first electrode and the second electrode, respectively,
wherein a plurality of openings for permitting the plural electron beams to pass therethrough, respectively, are formed in the upper electrode, the first electrode, the second electrode, and the lower electrode, respectively,
wherein the plural openings corresponding to at least a portion of the plural electron beams, formed in the first electrode, differs in opening diameter from the second electrode,
wherein the plural openings formed in an electrode on at least one side of the first electrode and the second electrode have not less than two types of opening diameters, and
wherein the first voltage and the second voltage are independently applied in sync with the signal for controlling the deflector.

11. The electron beam apparatus according to claim 1, wherein the parameter to be changed by the optical system adjustment unit is any selected from the group consisting of an acceleration voltage of the electron gun, a magnification of the irradiation optical system, or the projection optical system, energy of the primary beam falling on the specimen, the intensity of an electric field in the vicinity of the surface of the specimen, an interval between the adjacent beams of the plural electron beams projected on the specimen, and a current of the electron beam falling on the specimen.

12. A lens array for causing a plurality of electron beams arranged around a reference axis to be converged on individual axes, respectively, thereby forming an image-forming surface of the plural electron beams, comprising:
a unit that independently controls an image forming position of one of electron beam among the plural electron beams, serving as a reference, and a curvature of the image-forming surface.

13. The lens array according to claim 12, further comprising an upper electrode, a first electrode, a second electrode, and a lower electrode, sequentially disposed in an extension direction of a reference axis,
wherein a first voltage and a second voltage are independently applied to the first electrode and the second electrode, respectively,
wherein a plurality of openings for permitting the plural electron beams to pass therethrough, respectively, are formed in the upper electrode, the first electrode, the second electrode, and the lower electrode, respectively,
wherein the plural openings corresponding to at least a portion of the plural electron beams, formed in the first electrode, differs in opening diameter from the second electrode, and
wherein the plural openings formed in an electrode on at least one side of the first electrode and the second electrode have not less than two types of opening diameters.

14. The lens array according to claim 13, wherein the upper electrode, the first electrode, the second electrode, and the lower electrode each are a thin plates to be piled up with an insulator sandwiched between the respective electrodes adjacent to each other.

15. The lens array according to claim 14,
wherein the plural openings formed in either one electrode of the first electrode and the second electrode have not less than two types of opening diameters, and
wherein the plural openings formed in the other electrode of the first electrode and the second electrode have one type of opening diameter.

16. The lens array according to claim 12, further comprising a unit for keeping a principal plane of the lens array at a predetermined location.

17. The lens array according to claim 16, further comprising an upper electrode, a first electrode, a second electrode, and a lower electrode, sequentially disposed in the extension direction of a reference axis,
wherein a first voltage in common use is applied to the first electrode, and the third electrode, respectively,
wherein a second voltage independent from the first voltage is applied to the second electrode,
wherein a plurality of openings for permitting the plural electron beams to pass therethrough, respectively, are formed in the upper electrode, the first electrode, the second electrode, and the lower electrode, respectively,
wherein the plural openings corresponding to the plural electron beams, respectively, formed in the first electrode, are identical in opening diameter to the third electrode,
wherein the plural openings corresponding to at least a part of the plural electron beams, formed in the second electrode, differs in opening diameter from the first and third electrodes, and
wherein the plural openings formed in an electrode on the second electrode and at least one of the first and third electrodes have not less than two types of opening diameters.

18. The lens array according to claim 16, further comprising an upper electrode, a first electrode, a second electrode, and a lower electrode, sequentially disposed in the extension direction of a reference axis,
wherein first, second, and third voltages are independently applied to the first, second and third electrodes, respectively,
wherein a plurality of openings for permitting the plural electron beams to pass therethrough, respectively, are formed in the upper electrode, the first electrode, the second electrode, and the lower electrode, respectively,
wherein the plural openings corresponding to at least a portion of the plural electron beams, in the first electrode, differs in opening diameter from the second electrode, and the third electrode, and
wherein the plural openings formed in at least one of electrode selected from the first, second, and third electrodes, have not less than two types of opening diameters.

19. A lens array comprising:
a plurality of electrodes sequentially disposed in an extension direction of a reference axis; and
voltage sources for applying respective voltages to the plural electrodes, the lens array causing a plurality of electron beams passing in parallel with each other in the extension direction of the reference axis to be individually converged, thereby forming an image-forming surface of the plural electron beams,
wherein the plural electrodes include an upper electrode disposed on the upstream side of the extension direction of the reference axis,
wherein a plurality of openings for permitting the plural electron beams to pass therethrough, respectively, are formed, a lower electrode disposed on the downstream side of the extension direction of the reference axis,
wherein a plurality of openings for permitting the plural electron beams to pass therethrough, respectively, are formed, a first electrode disposed between the upper electrode and the lower electrode,
wherein a plurality of openings for permitting the plural electron beams to pass therethrough, respectively, are formed, and a second electrode disposed either in the upstream or the downstream of the first electrode between the upper electrode and the lower electrode,
wherein a plurality of openings for permitting the plural electron beams to pass therethrough, respectively, are formed, respective opening diameters of the plural openings formed in the first electrode are set on the basis of a first opening diameter distribution as preset, respective opening diameters of the plural openings formed in the second electrode are set on the basis of a second opening diameter distribution as preset, differing from the first opening diameter distribution, and the voltage sources individually control the respective voltages of the first electrode, and the second electrode.

20. The lens array according to claim 19, further comprising a third electrode disposed either in the upstream or the downstream of the first electrode between the upper electrode and the lower electrode,
wherein a plurality of openings for permitting the plural electron beams to pass therethrough, respectively, are formed, wherein respective opening diameters of the plural openings formed in the third electrode are set on the basis of the second opening diameter distribution, and
wherein the voltage sources control the voltage in common with the second electrode and the third electrode, controlling the voltage of the first electrode independently from the voltage of the second and the third electrodes.
